(19) United States
(12) Patent Application Publication
(10) Pub. No.: US 2015/0243535 A1
(43) Pub. Date: Aug. 27, 2015

(54) CLUSTER TYPE SEMICONDUCTOR PROCESSING APPARATUS AND METHOD FOR MANUFACTURING SEMICONDUCTOR DEVICE USING THE SAME

(71) Applicant: STS SEMICONDUCTOR & TELECOMMUNICATIONS CO., LTD., Cheonan-si (KR)

(72) Inventors: Eun Soo LEE, Cheonan-si (KR); Hee Cheol KIM, Cheonan-si (KR); Sung Yong KIM, Cheonan-si (KR); Seung Tae LEE, Cheonan-si (KR); Ig Jun SHIN, Cheonan-si (KR)

(21) Appl. No.: 14/335,110

(22) Filed: Jul. 18, 2014

(30) Foreign Application Priority Data
Feb. 21, 2014 (KR) 10-2014-0020397

(51) Int. Cl. H01L 21/67; C23C 14/34; H01J 37/34; C23C 14/02; H01L 21/285; H01L 21/02

(52) U.S. Cl. CPC H01L 21/67167; H01L 21/67207; H01L 21/2855; H01L 21/02068; H01J 37/3411; C23C 14/021; C23C 14/34; H01J 2237/3322

(57) ABSTRACT

A cluster type semiconductor processing apparatus and a method for manufacturing a semiconductor device using the same are provided. The cluster type semiconductor processing apparatus includes a polyhedral transfer module to transfer a wafer, a first process module communicating with the transfer module, a degassing process of removing fumes from a surface of the wafer being performed in the first process module, a second process module communicating with the transfer module, a plasma cleaning process of cleaning the surface of the wafer being performed in the second process module, a standby module communicating with the transfer module, the wafer having undergone the degassing process and the plasma cleaning process being maintained in the standby module for a certain time, and a third process module communicating with the transfer module, a metal sputtering process of depositing a metal film on the wafer being performed in the third process module.

### BACKGROUND OF THE INVENTION

1. Field of the Invention

The present invention relates to a cluster type semiconductor processing apparatus configured to execute sequential processes upon a wafer transferred sequentially along a plurality of process modules, and a method for manufacturing a semiconductor device using the same.

2. Description of the Related Art

In general, a cluster type semiconductor processing apparatus includes a plurality of process modules connected around a main transfer chamber (a common transfer chamber). The cluster type semiconductor processing apparatus may allow a smooth flow of processes or integrates various process flows enabling execution of various processes (see, for example, Japanese Patent Application Publication No. 2000-127069).

For example, the cluster type semiconductor processing apparatus used in forming a thin film includes a load-lock module connected to the main transfer chamber via a gate valve. When a specific process is executed on a processing substrate (hereinafter, simply referred to as “substrate”) such as a semiconductor wafer (hereinafter, simply referred to as “wafer”), the main transfer chamber and a separate process module chamber are held in a vacuum state. After the wafer is transferred to the load-lock module at an atmospheric pressure, the pressure of the load-lock module is reduced to a low pressure (vacuum pressure). Then, the wafer is withdrawn from the load-lock module in the vacuum state, and then introduced into the main transfer chamber by a transfer mechanism (e.g., a robot arm) installed in the main transfer chamber. Then, the wafer is introduced into a first process module from the main transfer chamber by the transfer mechanism.

In the first process module, a first process step is executed for a time predetermined by a preset recipe. During the first process step, for example, film formation may be implemented such that a first thin film layer is formed on the wafer. When the first process step is terminated, the wafer having undergone the first step is withdrawn from the first process module and introduced into a second process module by the transfer mechanism installed in the main transfer chamber.

In the second process module, a second process step is executed for a time predetermined by the preset recipe, as in the first process module. During the second process step, for example, film formation is implemented such that a second thin film layer is formed over the first layer formed on the wafer. When the second process step is terminated, the wafer having undergone the second step is withdrawn from the second process module by the transfer mechanism in the main transfer chamber. If the wafer is subjected to a sub-process step, the wafer is transferred to the next process module (e.g., a third process module) and undergoes the next process. Accordingly, the semiconductor wafer undergoes various process steps, and after all the process steps have been completed, the semiconductor wafer returns to the load-lock module.

When the processed wafer having undergone a series of process steps in the individual processes returns to the load-lock module, the internal pressure of the load-lock module is converted from the vacuum pressure to the atmospheric pressure. Then, the processed wafer is withdrawn from the load-lock module through a wafer inlet/outlet positioned at a side portion of the load-lock module facing the opposing side portion of the load-lock module connected to the main transfer chamber.

Such cluster type apparatus is intended to be applied to an inline substrate process system, in which a batch of wafers sequentially transferred to a plurality of process modules at the vacuum pressure one at a time undergoes a series of treatments (e.g., film formation and heat treatment).

In the bumping/under bump metallurgy (UBM) process, removal of fumes (outgassing) and plasma cleaning, i.e., soft etching, are performed on the wafer surface or a passivation coating applied surface before the metal sputtering process is performed in a cluster type sputter element.

When a process is performed in a metal sputtering chamber after the plasma cleaning process, additional fumes are produced from the finely etched passivation surface.

Therefore, additional time is taken to meet the operation condition (the chamber pressure) in the metal sputtering chamber, and thus the wafers per hour of the whole equipment may decrease.

### SUMMARY OF THE INVENTION

The present invention has been made in view of the above problems, and it is an object of the present invention to provide a cluster type semiconductor processing apparatus that can substantially address the limits and disadvantages of the conventional art and a method for manufacturing a semiconductor device using the same.

It is another object of the present invention to provide a cluster type semiconductor processing apparatus which can reduce a standby time for a proper pressure necessary for a process and a method for manufacturing a semiconductor device using the same.

It is a further object of the present invention to provide a cluster type semiconductor processing apparatus which can reduce a standby time for a proper pressure necessary for the metal sputtering process and a method for manufacturing a semiconductor device using the same.

In accordance with an aspect of the present invention, the above and other objects can be accomplished by the provision of a cluster type semiconductor processing apparatus including a polyhedral transfer module to transfer a wafer, a first process module communicating with the transfer module through a first face of the transfer module, and configured to perform a degassing process of removing fumes from a surface of the wafer, a second process module communicating with the transfer module through a second face of the transfer module, a plasma cleaning process of cleaning the surface of the wafer being performed in the second process module, a standby module communicating with the transfer module through a third face of the transfer module, the wafer having undergone the degassing process and the plasma cleaning process being maintained in a standby state in the standby module for a certain time, and a third process module communicating with the transfer module through a fourth face of the transfer module, and configured to perform a metal sputtering process of depositing a metal film on the wafer having been maintained in the standby state in the standby module.

The standby module may be a vacuum chamber.

The third process module may be a metal sputtering chamber.

The polyhedral transfer module may be provided with a vacuum chamber to transfer individual wafers in a vacuum atmosphere.

In accordance with another aspect of the present invention, there is provided a method of manufacturing a semiconductor device using a cluster type semiconductor processing apparatus, the method including a first process of loading a wafer onto the cluster type semiconductor processing apparatus maintaining a vacuum atmosphere, a second process of removing fumes from a surface of the wafer through a degassing process, a third process of cleaning the surface of the wafer through a plasma cleaning process, a fourth process of maintaining the wafer having undergone the second and third processes in a standby state in the vacuum atmosphere for a certain time, and a fifth process of depositing a metal film on the wafer through a metal sputtering process.

In accordance with a further aspect of the present invention, there is provided a method of manufacturing a semiconductor device using a cluster type semiconductor processing apparatus including a polyhedral transfer module, first, second and third process modules respectively communicating with the polyhedral transfer module through first, second and third faces of the polyhedral transfer module, and a standby module communicating with the polyhedral transfer module through a fourth face of the polyhedral transfer module, the method including a first process of loading a wafer onto the polyhedral transfer module, a second process of transferring the wafer to the first process module and removing fumes from a surface of the wafer through a degassing process, a third process of transferring the wafer to the second process module and cleaning the surface of the wafer through a plasma cleaning process, a fourth process of transferring the wafer having undergone the second and third processes to the standby module and maintaining the wafer in the standby module in a standby state and in a vacuum atmosphere for a certain time, and a fifth process of transferring the wafer to the third process module and depositing a metal film on the wafer through a metal sputtering process.

The polyhedral transfer module may individually transfer wafers in the vacuum atmosphere.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view schematically illustrating the configuration of a cluster type semiconductor processing apparatus according to one embodiment of the present invention; and

FIG. 2 is a flowchart illustrating a method for manufacturing a semiconductor device using a cluster type semiconductor processing apparatus according to one embodiment of the present invention.

### DETAILED DESCRIPTION OF THE INVENTION

Reference will now be made in detail to embodiments of the present invention, examples of which are illustrated in the accompanying drawings.

In describing the present invention, a detailed description of well-known functions and constituents will be omitted if it is determined that such description can unnecessarily obscure the main points of the present invention. In addition, terms which will be used below are defined in consideration of the functions of the corresponding elements in the present invention. The definitions of the terms may vary depending on intention of a user, precedent, or the like. Therefore, the terms should be defined based on the entire specification.

Hereinafter, a substrate processing system according to one embodiment of the present invention will be described with reference to the drawings.

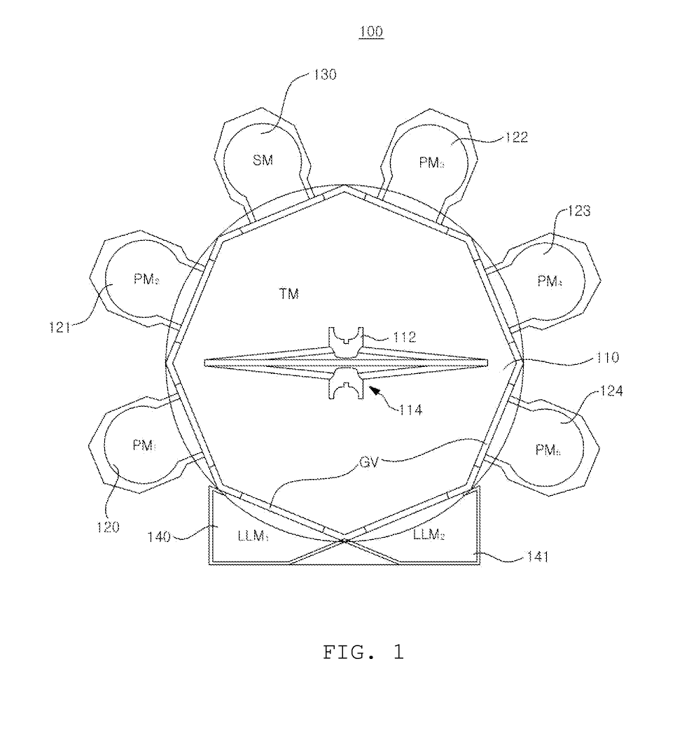

FIG. 1 is a view schematically illustrating the configuration of a cluster type semiconductor processing apparatus according to one embodiment of the present invention.

Referring to FIG. 1, the cluster type semiconductor processing apparatus 100 includes plural (e.g., five) process modules (processing apparatuses, PM1, PM2, PM3, PM4, and PM5) 120 to 124 arranged around a transfer module (vacuum transfer chamber, TM) 110, a standby module SM 130, and two load-lock modules (load-lock chambers, LLM1 and LLM2) 140 and 141.

The transfer module (TM) 110 disposed at the substantial center of the cluster type semiconductor processing apparatus 100 is connected to the respective modules PM1, PM2, PM3, PM4, PM5, SM, LLM1 and LLM2 via each gate valve GV which can be freely opened and closed.

Each of the process modules (PMs) 120 to 124 includes a vacuum chamber (or a process chamber) in which pressure can be reduced to achieve a degree of vacuum necessary for the corresponding process.

The transfer module (vacuum transfer chamber) TM 110 is a common transfer chamber to withdraw/introduce a wafer from each of the process modules PM1, PM2, PM3, PM4 and PM5 into a vacuum chamber.

A vacuum pressure transfer robot 114 provided with a pair of transfer arms 112 allowing such movements as rotation and expansion/contraction is installed and comprised in the vacuum transfer chamber 110. Each of the transfer arms 112 of the vacuum pressure transfer robot 114 includes a fork-shaped end effector (also referred to as “pick”) capable of holding one substrate such as a wafer.

The vacuum pressure transfer robot 114 is configured to access each of the modules PM1, PM2, PM3, PM4, PM5, SM, LLM1 and LLM2 to introduce or withdraw a wafer. The vacuum pressure transfer robot 114 includes a base rotatably disposed in the common transfer chamber 110 and provided with the transfer arms 112 mounted thereon in parallel to expand/contract, for example, in opposite directions.

Accordingly, the transfer arms 112 can rotate like an integrated unit via the base.

In the process modules PM1, PM2, PM3, PM4 and PM5, specific types of wafer processes (a process of film formation achieved through Chemical Vapor Deposition (CVD) or sputtering and a recipe process performed based on a process recipe such as a heat treatment and dry etching process) is performed in accordance with a predetermined recipe in each chamber under specific process conditions (gas type, chamber pressure, applied power level, process time, etc.). In addition, each of the load-lock modules (LLM1 and LLM2) 140 and 141 may include a heating unit or a cooling unit, when necessary.

The standby module SM 130 can be embodied by mounting a standby chamber to an empty module. That is, the standby module 130 is a module where a wafer temporarily stays before the wafer having undergone a process in a process module is transferred to the next process module. For example, before a wafer having undergone plasma cleaning in PM2 is moved to the metal sputtering module of PM3, the wafer is transferred to the standby module 130 such that discharge of fumes (outgassing) is performed under high vacuum. Thereby, time taken to reach the vacuum condition in the metal sputtering module may be reduced. At this time, the standby module SM 130 may be held in a vacuum state using a transfer module (TM) pump.

Hereinafter, a description will be given of a method for manufacturing a semiconductor using the cluster type semiconductor processing apparatus configured as above according to one embodiment.

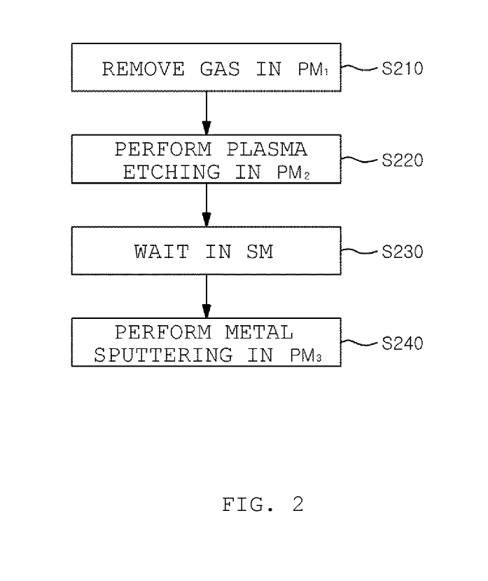

FIG. 2 is a flowchart illustrating a method for manufacturing a semiconductor device using a cluster type semiconductor processing apparatus according to one embodiment of the present invention. The flowchart illustrates the metal sputtering process in the under bump metallurgy (UBM) process.

Referring to FIG. 2, before the metal sputtering process is conducted, a wafer is introduced into a degassing process module PM1 120 and fumes are primarily removed from the wafer surface or the passivation coating applied surface (S210).

Next, the wafer is transferred to an etching process module PM2 121 and plasma etching of the wafer surface or the passivation coating applied surface is performed (S220).

Next, the wafer is transferred to the standby module SM 130 and maintained in the standby state for a certain time. While the wafer is in the standby state in the standby module SM 130, fumes continue to be generated from the plasma-etched surface, and a vacuum pump is used to maintain a degree of vacuum in the standby module SM 130 similar to that of the transfer module TM (S230).

Next, the wafer is transferred to the metal sputtering module PM3 122, and the metal layer deposition process is performed (S240). Generally, in the TiW deposition process, the pressure in the chamber should be pumped down below 5.0e-7 within 500 sec after the wafer is loaded in the chamber. According to this embodiment, in the case in which a wafer is held in the standby state in the standby module SM 130 before transfer from the etching process modules PM2 121 to the metal sputtering module PM3 122, the pump down time is between 110 sec and 120 sec, which is shorter than the conventional pump down time, which is between 270 sec and 300 sec, by about 160 sec to 180 sec.

According to this embodiment, in the metal sputtering process, a wafer is held in the standby state in the standby module SM so as to additionally discharge fumes before the wafer is transferred from the etching process modules PM2 to the metal sputtering module PM3. Therefore, a time taken to reduce the pressure in the metal sputtering module PM3 may be shortened, and thus WPH may increase by 4.

As is apparent from the above description, according to a cluster type semiconductor processing apparatus and a method for manufacturing a semiconductor device using the same in the present invention, in the metal sputtering process, a wafer is held in the standby state in the standby module SM so as to additionally discharge fumes before the wafer is transferred from the etching process modules PM2 to the metal sputtering module PM3. Therefore, a time taken to reduce the pressure in the metal sputtering module PM3 may be shortened, and thus WPH may increase.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Therefore, the scope of the present invention should not be limited to the illustrated embodiments, but should be construed as being defined by the claims and their equivalents.

What is claimed is:

1. A cluster type semiconductor processing apparatus comprising:
a polyhedral transfer module to transfer a wafer;
a first process module communicating with the transfer module through a first face of the transfer module, and configured to perform a degassing process of removing fumes from a surface of the wafer;
a second process module communicating with the transfer module through a second face of the transfer module, and configured to perform a plasma cleaning process of cleaning the surface of the wafer;
a standby module communicating with the transfer module through a third face of the transfer module, the wafer having undergone the degassing process and the plasma cleaning process being maintained in a standby state in the standby module for a certain time; and
a third process module communicating with the transfer module through a fourth face of the transfer module, and configured to perform a metal sputtering process of depositing a metal film on the wafer having been maintained in the standby state in the standby module.

2. The cluster type semiconductor processing apparatus according to claim 1, wherein the standby module is a vacuum chamber.

3. The cluster type semiconductor processing apparatus according to claim 1, wherein the third process module is a metal sputtering chamber.

4. The cluster type semiconductor processing apparatus according to claim 1, wherein the polyhedral transfer module includes a vacuum chamber to transfer the wafer in a vacuum atmosphere.

5. A method of manufacturing a semiconductor device using a cluster type semiconductor processing apparatus, the method comprising:
a first process of loading a wafer onto the cluster type semiconductor processing apparatus maintaining a vacuum atmosphere;
a second process of removing fumes from a surface of the wafer through a degassing process;
a third process of cleaning the surface of the wafer through a plasma cleaning process;
a fourth process of maintaining the wafer having undergone the second and third processes in a standby state in the vacuum atmosphere for a certain time; and
a fifth process of depositing a metal film on the wafer through a metal sputtering process.

6. A method of manufacturing a semiconductor device using a cluster type semiconductor processing apparatus including a polyhedral transfer module, first, second and third process modules respectively communicating with the polyhedral transfer module through first, second and third faces of the polyhedral transfer module, and a standby module communicating with the polyhedral transfer module through a fourth face of the polyhedral transfer module, the method comprising:
a first process of loading a wafer onto the polyhedral transfer module;
a second process of transferring the wafer to the first process module and removing fumes from a surface of the wafer through a degassing process;
a third process of transferring the wafer to the second process module and cleaning the surface of the wafer through a plasma cleaning process;
a fourth process of transferring the wafer having undergone the second and third processes to the standby module and maintaining the wafer in the standby module in a standby state and in a vacuum atmosphere for a certain time; and
a fifth process of transferring the wafer to the third process module and depositing a metal film on the wafer through a metal sputtering process.

7. The method according to claim 6, wherein the polyhedral transfer module includes a vacuum chamber, thereby transferring the wafer in the vacuum atmosphere.
